(19) United States
(12) Patent Application Publication
(10) Pub. No.: US 2024/0178081 A1
(43) Pub. Date: May 30, 2024

(54) SEMICONDUCTOR MODULE, SEMICONDUCTOR DEVICE, AND METHOD FOR MANUFACTURING SEMICONDUCTOR DEVICE

(71) Applicant: FUJI ELECTRIC CO., LTD., Kawasaki-shi (JP)

(72) Inventor: Kazuo ENOMOTO, Kawasaki-shi (JP)

(73) Assignee: FUJI ELECTRIC CO., LTD., Kawasaki-shi (JP)

(21) Appl. No.: 18/428,381

(22) Filed: Jan. 31, 2024

Related U.S. Application Data
(63) Continuation of application No. PCT/JP2022/047924, filed on Dec. 26, 2022.

(30) Foreign Application Priority Data
Feb. 21, 2022 (JP) 2022-025012

(51) Int. Cl. H01L 23/049; H01L 23/13; H01L 23/14; H01L 25/07

(52) U.S. Cl. CPC H01L 23/049; H01L 23/13; H01L 23/14; H01L 25/072

(57) ABSTRACT

A semiconductor module a metal base plate having a semiconductor unit including a semiconductor element, the metal base plate having an upper surface and a bottom surface opposite to each other and the semiconductor element being mounted on the upper surface, and a case surrounding a periphery of the semiconductor unit and being bonded to the upper surface of the metal base plate. The case includes a first positioning portion formed by a protrusion protruding a bottom of the case toward the metal base plate, and a second positioning portion formed by a hole or a cutout so as to at least partially overlap with the first positioning portion in a plan view of the semiconductor module. The metal base plate includes a first engagement portion formed by a hole or a cutout with which the first positioning portion is engageable.

### CROSS REFERENCE TO RELATED APPLICATIONS

This is a continuation application of International Application PCT/JP2022/047924 filed on Dec. 26, 2022 which claims priority from a Japanese Patent Application No. 2022-025012 filed on Feb. 21, 2022, the contents of which are incorporated herein by reference.

### TECHNICAL FIELD

The present invention relates to a semiconductor module, a semiconductor device, and a method for manufacturing a semiconductor device.

### BACKGROUND ART

A semiconductor module has a substrate on which a semiconductor element such as an insulated gate bipolar transistor (IGBT), a power metal oxide semiconductor field effect transistor (power MOSFET), and a free wheeling diode (FWD) is provided, and is used in an inverter device and the like.

For example, in a semiconductor device described in Patent Literature 1, a main semiconductor module is disposed on the upper surface of a heat sink. The periphery of the semiconductor module is surrounded by a housing. A housing cover is provided on the upper surface of the housing. A printed circuit board is provided on the upper side of the housing cover.

Further, in Patent Literature 1, protrusions extending in the vertical direction are formed on the upper surface and the lower surface of the housing, respectively. Each of the protrusions functions as an adjustment pin for adjusting the position of the housing. For example, through holes are formed in the substrate of the semiconductor module and the heat sink located on the lower side of the housing, respectively. The protrusion on the lower surface side of the housing is inserted into the respective through holes. Accordingly, positioning of the housing with respect to the semiconductor module and the heat sink is achieved.

Similarly, through holes are formed in the housing cover and the printed circuit board located on the upper side of the housing as well. The protrusion on the upper surface side of the housing is inserted into the respective through holes. Accordingly, positioning of the housing cover and the printed circuit board with respect to the housing is achieved.

### CITATION LIST

### Patent Literature

Patent Literature 1: U.S. Pat. No. 9,888,601

Patent Literature 2: JP 2016-51878 A

Patent Literature 3: JP 2012-142521 A

Patent Literature 4: JP 2010-114257 A

Patent Literature 5: JP 2022-74234 A

Patent Literature 6: WO 2018/055667 A

Patent Literature 7: JP 2005-322784 A

### SUMMARY OF INVENTION

### Technical Problem

However, in Patent Literature 1, since the plurality of protrusions are provided on the upper surface and the lower surface of the housing, respectively, the shape of the entire housing is complicated. This can cause a cost increase as a whole.

The present invention has been made in view of such a point, and an object of the present invention is to provide a semiconductor module, a semiconductor device, and a method for manufacturing a semiconductor device that can simplify a configuration, reduce cost, and facilitate assembly work and attachment work.

### Solution to Problem

A semiconductor module according to an aspect of the present invention includes a metal base plate on an upper surface of which a semiconductor unit including a semiconductor element is mounted, and a case which is bonded to the upper surface of the metal base plate and surrounds a periphery of the semiconductor unit. The case includes a first positioning portion formed by a protrusion protruding toward the metal base plate, and a second positioning portion formed by a hole or a cutout so as to at least partially overlap with the first positioning portion in a planar view. The metal base plate includes a first engagement portion formed by a hole or a cutout with which the first positioning portion is engageable.

### Advantageous Effects of Invention

According to the present invention, it is possible to simplify a configuration, reduce cost, and facilitate assembly work and attachment work.

### BRIEF DESCRIPTION OF DRAWINGS

FIG. 1 is a perspective view of a semiconductor device according to an embodiment.

FIG. 2 is a plan view of the semiconductor device in FIG. 1 in which a sealing resin is omitted.

FIG. 3 is a cross-sectional view of the semiconductor device illustrated in FIG. 2 taken along line X-X.

FIG. 4 is a cross-sectional view of the semiconductor device illustrated in FIG. 2 taken along line Y-Y.

FIG. 5 is an equivalent circuit diagram of a semiconductor module according to the present embodiment.

FIG. 6 is a perspective view illustrating a process example of a method for manufacturing a semiconductor device according to the present embodiment.

FIG. 7 is a perspective view illustrating a process example of the method for manufacturing a semiconductor device according to the present embodiment.

FIG. 8 is a perspective view illustrating a process example of the method for manufacturing a semiconductor device according to the present embodiment.

FIGS. 9A, 9B, and 9C illustrate schematic cross-sectional views enlarging a part of the process illustrated in FIG. 8.

FIGS. 10A and 10B are perspective views illustrating a process example of the method for manufacturing a semiconductor device according to the present embodiment.

FIG. 11 is a perspective view illustrating a process example of the method for manufacturing a semiconductor device according to the present embodiment.

FIGS. 12A, 12B, and 12C illustrate schematic cross-sectional views enlarging a part of the process illustrated in FIG. 11.

FIGS. 13A, 13B, and 13C illustrate schematic views of a variation of the semiconductor device according to a modification example.

FIGS. 14A, 14B, and 14C illustrate schematic views of another modification example.

### DESCRIPTION OF EMBODIMENTS

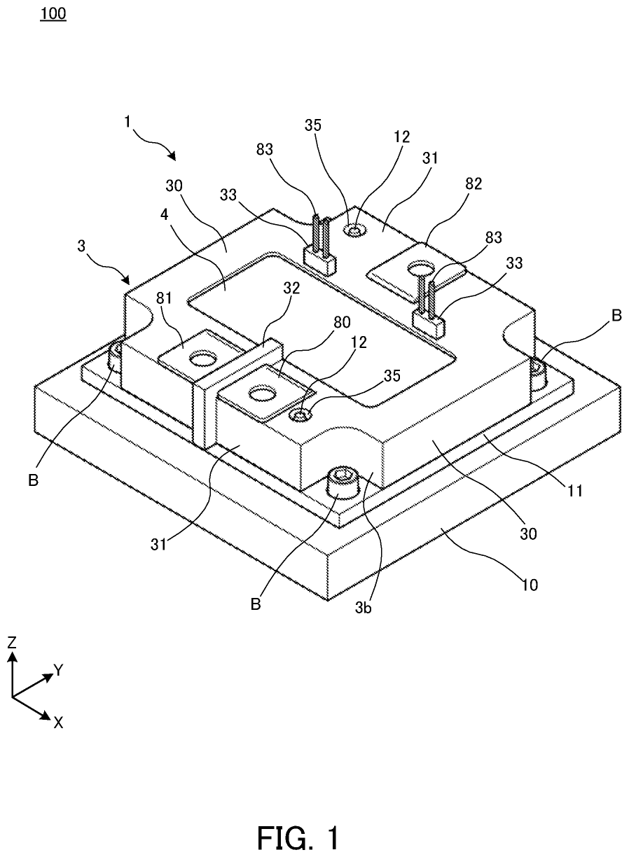

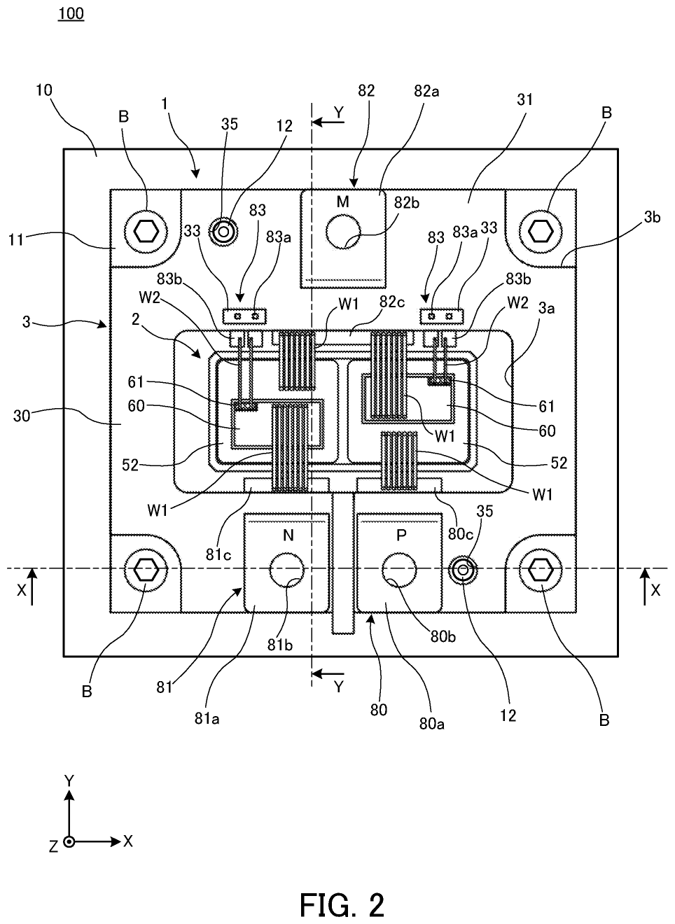

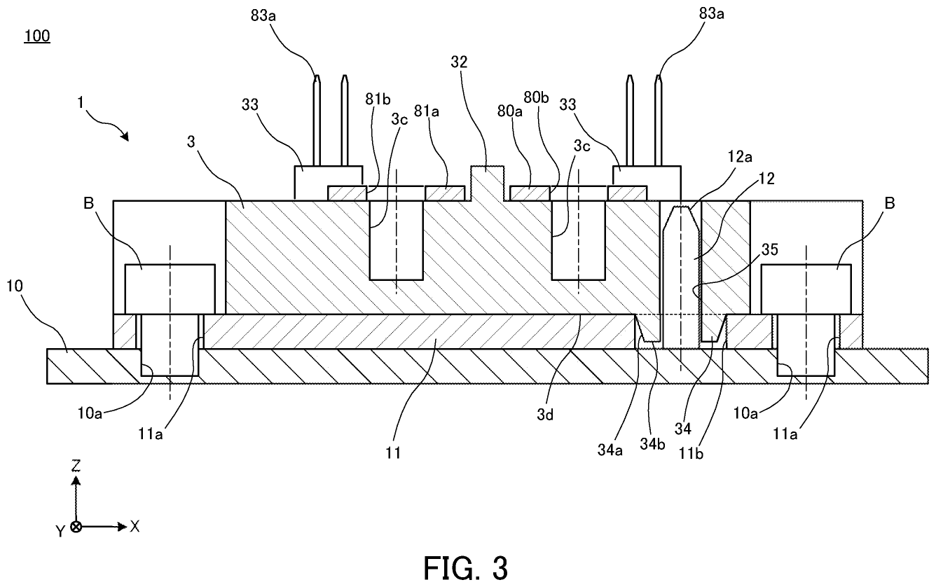

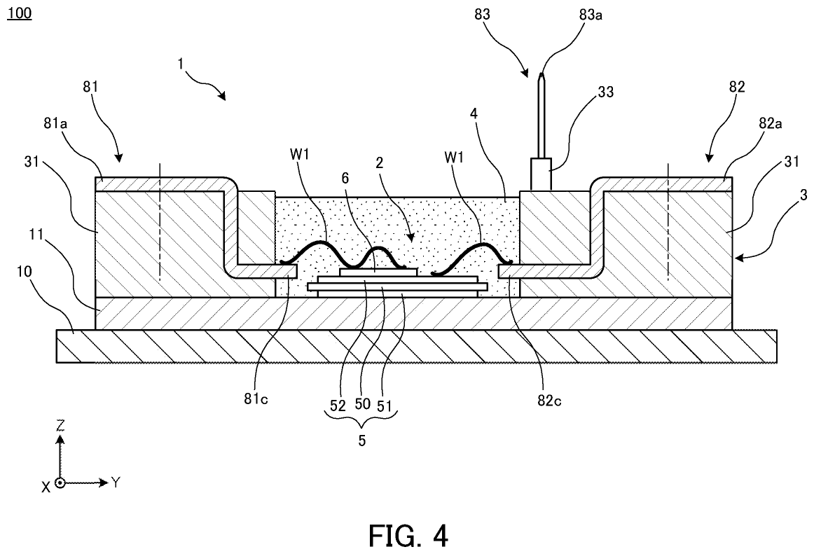

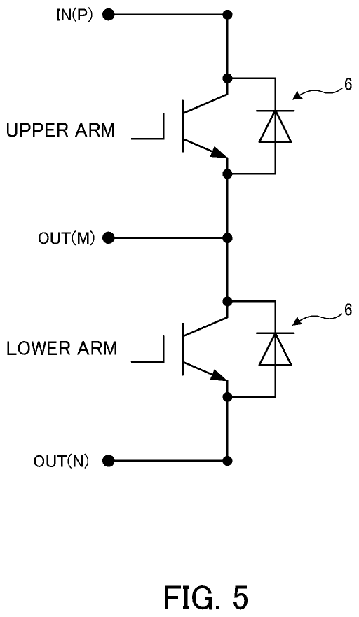

Hereinbelow, a semiconductor device to which the present invention can be applied will be described. FIG. 1 is a perspective view of a semiconductor device according to an embodiment. FIG. 2 is a plan view of the semiconductor device in FIG. 1 in which a sealing resin is omitted. FIG. 3 is a cross-sectional view of the semiconductor device illustrated in FIG. 2 taken along line X-X. FIG. 4 is a cross-sectional view of the semiconductor device illustrated in FIG. 2 taken along line Y-Y. FIG. 5 is an equivalent circuit diagram of the semiconductor device according to the present embodiment.

In the following drawings, a longitudinal direction of the semiconductor module is defined as an X direction, a lateral direction of the semiconductor module is defined as a Y direction, and a height direction (a direction of the thickness of a substrate) is defined as a Z direction. The longitudinal direction of the semiconductor module indicates a direction in which a plurality of semiconductor units are arrayed. X, Y, and Z axes illustrated are orthogonal to each other and form a right-handed system. In some cases, the X direction may be referred to as a right-left direction, the Y direction may be referred to as a front-rear direction, and the Z direction may be referred to as an up-down direction. Further, the +Z direction may be referred to as an upper side, and the −Z direction may be referred to as a lower side. In addition, the position on the +Z side may be referred to as a high position, and the position on the −Z side may be referred to as a low position. These directions (front-rear, right-left, and up-down directions) and height are terms used for convenience of description, and the correspondence relationships thereof with the XYZ directions, respectively, may change depending on the attachment posture of the semiconductor module. For example, a heat dissipation surface side (cooler side) of the semiconductor module is referred to as a lower surface side, and the opposite side is referred to as an upper surface side. In the present specification, the term “in a planar view” means a case where an upper surface or a lower surface of the semiconductor module is viewed in the Z direction. In addition, the ratio between the width and the thickness and the size relationship between the members in the drawings are illustrated in schematic views, and thus are not necessarily the same among the drawings. For convenience of description, it is also assumed that the size relationship between the members may be exaggerated.

A semiconductor device 100 according to the present embodiment is applied to, for example, a power conversion device such as an inverter of an industrial or in-vehicle motor. As illustrated in FIGS. 1 to 4, the semiconductor device 100 is configured by arranging a semiconductor module 1 on the upper surface of an attaching target base 10. Note that the attaching target base 10 is a selective component for the semiconductor module 1.

The attaching target base 10 releases heat of the semiconductor module 1 to the outside, and has a rectangular shape in a planar view. The semiconductor module 1 is integrally secured to the attaching target base 10 by screwing bolts B at four corners into the attaching target base 10. The detailed configuration of the attaching target base 10 will be described below.

The semiconductor module 1 includes a metal base plate 11, a semiconductor unit 2, a case 3 housing the semiconductor unit 2, and a sealing resin 4 injected into the case 3.

The metal base plate 11 has a rectangular shape in a planar view and includes a plate-like body having a predetermined thickness. The metal base plate 11 may be made of a metal material having good heat dissipation properties, such as aluminum, an aluminum alloy, copper, and a copper alloy. Alternatively, the metal base plate 11 may be made of a metal matrix composite material such as a composite material of aluminum and silicon carbide (Al—SiC) and a composite material of magnesium and silicon carbide (Mg—SiC).

The semiconductor unit 2 and the case 3 are mounted on the upper surface of the metal base plate 11. More specifically, the semiconductor unit 2 is bonded to the center of the upper surface of the metal base plate 11 via a bonding material (not illustrated) such as solder. The case 3 is bonded to the outer peripheral side of the upper surface of the metal base plate 11 via a bonding material (not illustrated) such as an adhesive. A region surrounded by the upper surface of the metal base plate 11 and the case 3 is filled with a sealing resin 4. The upper surface of the metal base plate 11 may be flat. The lower surface of the metal base plate 11 is a surface to be attached to the attaching target base 10, which is an attaching target for the semiconductor module 1, and functions as a heat dissipation surface (heat dissipation region) for dissipating heat of the semiconductor module 1. The metal base plate 11 may be disposed on the upper surface of the attaching target base 10 via a thermal conductive material such as a thermal grease and a thermal compound. The lower surface of the metal base plate 11 may be flat. Also, the metal base plate 11 may be provided on the lower surface thereof with a protrusion such as a cooling fin. The metal base plate 11 may be provided inside with a flow path through which a refrigerant flows.

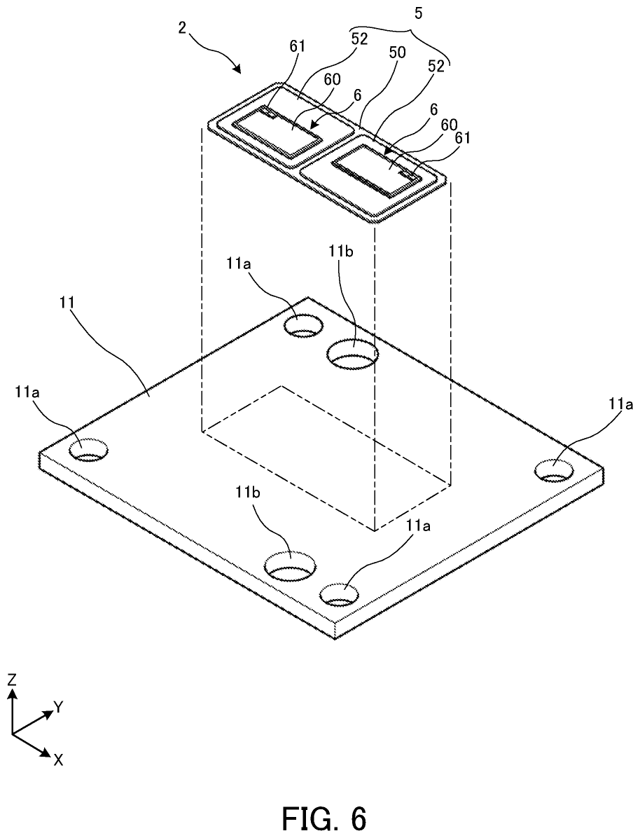

The metal base plate 11 is provided at four corners thereof with through holes 11a (refer to FIGS. 3 and 6). The through holes 11a function as insertion holes for the bolts B when the semiconductor module 1 is attached to the attaching target base 10. Also, in the metal base plate 11, another through hole 11b is formed in the vicinity of a predetermined through hole 11a. The through hole 11b has a circular shape in a planar view. The through hole 11b has a cylindrical surface perpendicular to the front surface of the metal base plate 11. That is, the through hole 11b is formed by a cylindrical space having an axis in the Z direction. Two through holes 11b are disposed to be opposed to each other diagonally with the semiconductor unit 2 interposed therebetween in a planar view. Although details will be described below, the through hole 11b functions as an engagement portion (first engagement portion) for positioning the case 3.

The semiconductor unit 2 includes a stacked substrate 5 and two semiconductor elements 6 disposed on the stacked substrate 5. In the present embodiment, two semiconductor elements 6 are arranged side by side in the X direction on the upper surface of one stacked substrate 5. Note that the semiconductor unit 2 may be referred to as a power cell.

The stacked substrate 5 includes, for example, a direct copper bonding (DCB) substrate, an active metal brazing (AMB) substrate, or a metal base substrate. The stacked substrate 5 is formed by stacking an insulating plate 50, a heat dissipation plate 51, and a plurality of interconnect plates 52, and has a rectangular shape as a whole in a planar view.

Specifically, the insulating plate 50 includes a plate-like body having an upper surface and a lower surface, and has a rectangular shape elongated in the X direction in a planar view. The insulating plate 50 may be made of, for example, a ceramic material such as aluminum oxide (Al₂O₃), aluminum nitride (AlN), silicon nitride (Si₃N₄), and aluminum oxide (Al₂O₃) and zirconium oxide (Zro₂).

In addition, the insulating plate 50 may be made of, for example, a thermosetting resin such as an epoxy resin and a polyimide resin, or a composite material obtained by using glass or a ceramic material as a filler in a thermosetting resin. The insulating plate 50 preferably has flexibility and may be made of, for example, a material containing a thermosetting resin. Note that the insulating plate 50 may be referred to as an insulating layer or an insulating film.

The heat dissipation plate 51 has a predetermined thickness in the Z direction and has a rectangular shape elongated in the Y direction in a planar view. For example, the heat dissipation plate 51 is made of a metal plate having good thermal conductivity, such as copper and aluminum. The heat dissipation plate 51 is arranged on the lower surface of the insulating plate 50. The lower surface of the heat dissipation plate 51 is bonded to the upper surface of the metal base plate 11 via a bonding material (not illustrated) such as solder, and functions as a heat dissipation surface (heat dissipation region) for dissipating heat of the semiconductor unit 2.

Each of the plurality of interconnect plates 52 (two in the present embodiment) has a predetermined thickness and has an electrically independent island shape (for example, a rectangular shape in a planar view). The two interconnect plates 52 are arranged side by side in the X direction on the upper surface of the insulating plate 50. Note that the shapes, numbers, arrangement locations, and the like of the interconnect plates 52 can appropriately be changed without being limited thereto. These interconnect plates 52 each may be made of, for example, a metal plate having good thermal conductivity such as copper and aluminum. The interconnect plate 52 may be referred to as a circuit board, a circuit layer or a circuit pattern.

On the upper surface of each of the interconnect plates 52, the semiconductor element 6 is arranged via a bonding material (not illustrated) such as solder. The bonding material is only required to be a conductive material, and may be, for example, solder or a metal sintered material. The semiconductor element 6 is made of a semiconductor substrate such as silicon (Si) to have a rectangular shape in a planar view.

In addition, the semiconductor element 6 may include a wide bandgap semiconductor element (which may be referred to as a wide gap semiconductor element) made of a wide bandgap semiconductor substrate such as silicon carbide (Sic), gallium nitride (GaN), and diamond, instead of the above-described silicon.

As the semiconductor element 6, a switching element such as an insulated gate bipolar transistor (IGBT) and a power metal oxide semiconductor field effect transistor (power MOSFET), or a diode such as a free wheeling diode (FWD) may be used.

In the present embodiment, the semiconductor element 6 includes a reverse conducting (RC)-IGBT element into which the functions of the insulated gate bipolar transistor (IGBT) element and the free wheeling diode (FWD) element are integrated (for example, refer to FIG. 5).

Note that the semiconductor element 6 is not limited thereto, and may be configured by combining the above-described switching element, diode, and the like. For example, the IGBT element and the FWD element may be configured separately. Also, as the semiconductor element 6, a reverse blocking (RB)-IGBT or the like having a sufficient withstand voltage against a reverse bias may be used.

In addition, the shape, number, arrangement location, and the like of the semiconductor element 6 can appropriately be changed. For example, in the present embodiment, as illustrated in FIG. 5, one (positive side in the X direction) of the two semiconductor elements 6 may constitute an upper arm, and the other (negative side in the X direction) semiconductor element 6 may constitute a lower arm.

The semiconductor element 6 configured as described above has an upper surface and a lower surface in the XY plane, and an electrode is formed on each of the surfaces. For example, a main electrode 60 and a control electrode 61 are formed on the upper surface of the semiconductor element 6, and a main electrode (not illustrated) is formed on the lower surface of the semiconductor element 6. The main electrode 60 on the upper surface and the main electrode on the lower surface are electrodes through which main current flows, and each have a rectangular shape in a planar view, having an area occupying the large part of the upper surface of the semiconductor element 6. On the other hand, the control electrode 61 has a much smaller rectangular shape in a planar view than the main electrode 60. For example, in the present embodiment, a plurality of (two) control electrodes 61 are each arranged so as to be biased toward the corner of the semiconductor element 6. Note that the arrangement of the respective electrodes is not limited thereto, and can appropriately be changed.

For example, in a case where the semiconductor element 6 is a MOSFET element, the main electrode on the upper surface side may be referred to as a source electrode, and the main electrode on the lower surface side may be referred to as a drain electrode. Also, in a case where the semiconductor element 6 is an IGBT element, the main electrode on the upper surface side may be referred to as an emitter electrode, and the main electrode on the lower surface side may be referred to as a collector electrode.

Also, the control electrode 61 may include a gate electrode. The gate electrode is an electrode for controlling a gate for turning on and off the main current. Also, the control electrode 61 may include an auxiliary electrode. For example, the auxiliary electrode may be an auxiliary source electrode or an auxiliary emitter electrode electrically connected to the main electrode on the upper surface side and serving as a reference potential with respect to a gate potential. In addition, the auxiliary electrode may be a temperature sensing electrode which measures the temperature of the semiconductor element. Such electrodes (the main electrode 60 and the control electrode 61) formed on the upper surface of the semiconductor element 6 may be generally referred to as upper surface electrodes, and the electrode formed on the lower surface of the semiconductor element 6 may be referred to as a lower surface electrode.

In addition, the semiconductor element 6 in the present embodiment may be a so-called vertical switching element in which functional elements such as transistors are formed on the semiconductor substrate in a thickness direction, or a horizontal switching element in which these functional elements are formed in a plane direction.

The periphery of the semiconductor unit 2 is surrounded by the case 3. The case 3 has a rectangular annular tubular or frame shape in a planar view. The case 3 is made of, for example, a thermoplastic resin. Examples of the thermoplastic resin include a polyphenylene sulfide (PPS) resin, a polybutylene terephthalate (PBT) resin, a polybutylene succinate (PBS) resin, a polyamide (PA) resin, a poly ether ether ketone (PEEK) resin, and an acrylonitrile butadiene styrene (ABS) resin. An inorganic filler for improving strength and/or functionality may be mixed into the resin. The case 3 is molded by injection molding using such a thermoplastic resin. The case 3 may be referred to as a resin case or a resin portion. Also, in the case 3, a protrusion 34 and a through hole 35, which will be described below, are integrally formed.

The internal space defined by the case 3 is filled with the sealing resin 4. The case 3 may be filled with the sealing resin 4 until the upper surface of the sealing resin reaches the upper end of the case 3. By doing so, various components (semiconductor unit 2 (stacked substrate 5 and semiconductor element 6), wiring members W1 and W2 described below, and the like) disposed in the case 3 are sealed.

The sealing resin 4 may be made of, for example, a thermosetting resin. The sealing resin 4 preferably contains at least one of an epoxy resin, a silicone resin, a phenol resin, and a melamine resin. As the sealing resin 4, for example, an epoxy resin mixed with an inorganic filler is suitable from the viewpoint of insulating properties, heat resistance, and heat dissipation properties.

The case 3 has a rectangular frame shape and has an opening 3a at the center thereof. Specifically, the case 3 includes a pair of sidewalls 30 opposed to each other in the X direction and a pair of sidewalls 31 opposed to each other in the Y direction, and is formed into the rectangular frame shape by connecting the respective ends. The pair of sidewalls 31 is longer than the pair of sidewalls 30.

Cutouts 3b are formed at four corners of the case 3. The cutout 3b is formed so as to avoid the bolt B at a position corresponding to the through hole 11a of the metal base plate 11. This prevents the case 3 and the bolt B from interfering with each other.

In the internal space of the case 3, the above-described semiconductor unit 2 is housed. That is, the semiconductor unit 2 is housed in the space defined by the frame-like case 3. The lower end of the case 3 is bonded to the upper surface of the metal base plate 11 via, for example, an adhesive (not illustrated). The adhesive is preferably, for example, an epoxy-based or silicone-based adhesive. The detailed structure of the case 3 will be described below.

The case 3 is provided with main terminals (a P terminal 80, an N terminal 81, and an M terminal 82) for external connection and a control terminal 83 for control. More specifically, the P terminal 80 and the N terminal 81 are embedded in the sidewall 31 located on the negative side in the Y direction out of the paired sidewalls 31. The P terminal 80 and the N terminal 81 are arranged side by side in the X direction. The case 3 (the sidewall 31 on the negative side in the Y direction) is provided with a partition wall 32 that separates the P terminal 80 from the N terminal 81. Further, the M terminal 82 is embedded in the sidewall 31 located on the positive side in the Y direction out of the paired sidewalls 31.

Each of the main terminals has a crank shape in which a metal plate is bent at a plurality of places (refer to FIG. 4). For example, one end of the P terminal 80 includes a plate-like portion 80a having the upper surface and the lower surface. The plate-like portion 80a is exposed on the upper surface of the sidewall 31 and is provided at the center thereof with a circular hole 80b. The other end of the P terminal 80 includes a plate-like portion 80c having the upper surface and the lower surface. The plate-like portion 80c protrudes inward from the inside surface (opening 3a) of the sidewall 31.

Similarly, one end of the N terminal 81 includes a plate-like portion 81a having the upper surface and the lower surface. The plate-like portion 81a is exposed on the upper surface of the sidewall 31 and is provided at the center thereof with a circular hole 81b. The other end of the N terminal 81 includes a plate-like portion 81c having the upper surface and the lower surface. The plate-like portion 81c protrudes inward from the inside surface (opening 3a) of the sidewall 31.

Similarly, one end of the M terminal 82 includes a plate-like portion 82a having the upper surface and the lower surface. The plate-like portion 82a is exposed on the upper surface of the sidewall 31 and is provided at the center thereof with a circular hole 82b. The other end of the M terminal 82 includes a plate-like portion 82c having the upper surface and the lower surface. The plate-like portion 82c protrudes inward from the inside surface (opening 3a) of the sidewall 31.

The P terminal 80 may be referred to as a positive terminal (input terminal). The N terminal 81 may be referred to as a negative terminal (output terminal). The M terminal 82 may be referred to as a middle terminal (output terminal). Each of these terminals constitutes a metal interconnect plate through which the main current flows. One ends of the P terminal 80, the N terminal 81, and the M terminal 82 each constitute a main terminal connectable to an external conductor. As described above, one ends (plate-like portions 80c, 81c, and 82c) of the P terminal 80, the N terminal 81, and the M terminal 82 are each electrically connected to the semiconductor unit 2 via the predetermined wiring member W1. The P terminal 80, the N terminal 81, and the M terminal 82 correspond to P, N, and M in FIG. 5.

For example, each of these main terminals is made of a metal material, such as a copper material, a copper-alloy-based material, an aluminum-alloy-based material, and an iron-alloy-based material. Note that the shapes, arrangement locations, numbers, and the like of these terminals can appropriately be changed without being limited thereto.

A pair of column portions 33 protruding vertically in the Z direction is formed on the upper surface of the sidewall on the positive side in the Y direction. The column portion 33 has an elongated shape elongated in the X direction in a planar view along the opening 3a. Two column portions 33 are arranged side by side in the X direction. A plurality of control terminals 83 are embedded in the column portion 33. Two control terminals 83 are embedded in each of the column portions 33.

One end of the control terminal 83 includes a pin portion 83a protruding from the upper surface of the column portion 33 and extending upward in the Z direction. The other end of the control terminal 83 includes a plate-like portion 83b having the upper surface and the lower surface (refer to FIG. 2). The plate-like portion 83b protrudes inward from the inside surface (opening 3a) of the sidewall 31. Note that the number of the control terminals 83 arranged can appropriately be changed without being limited thereto.

The control terminal 83 is made of a metal material, such as a copper material, a copper-alloy-based material, an aluminum-alloy-based material, and an iron-alloy-based material. The control terminal 83 is integrally molded (insert-molded) so as to be embedded in the case 3.

In the case 3, a circular hole 3c having a predetermined depth is formed at a corresponding position immediately below each of the circular holes 80b, 81b, and 82b of the main terminals. These circular holes may function as screw holes for securing external terminals such as bus bars.

On the back surface side of the case 3, the protrusion 34 protruding downward from a flat surface 3d of the case 3 is formed. The protrusion 34 is formed integrally with the case 3. The protrusion 34 is disposed at a position opposed to the through hole 11b, that is, at a position overlapping with the through hole 11b in a planar view. The protrusion 34 has a circular shape in a planar view. For example, the protrusion 34 may have a truncated conical shape. The protrusion height of the protrusion 34 is preferably lower (shorter) than the thickness of the metal base plate 11.

More specifically, the protrusion 34 includes a tapered surface 34a whose outside surface reduces in diameter toward the tip end (downward in the Z direction), and a flat surface 34b connected to the tip end of the tapered surface 34a. The flat surface 34b is provided in parallel with the flat surface 3d and at a lower position than the flat surface 3d. That is, the back surface of the case 3 is formed by connecting the flat surface 3d, the tapered surface 34a, and the flat surface 34b.

The through hole 35 penetrating in the Z direction is formed at the center of the protrusion 34. That is, the protrusion 34 has a tapered cylindrical shape as a whole. Note that, although the through hole 35 is given as an example in the present embodiment, the hole provided in the protrusion 34 is not necessarily the through hole 35. For example, a hole having a predetermined depth may be formed. In this case, the depth of the hole provided in the protrusion 34 is deeper than the flat surface 3d, and more preferably deeper than the length of an engagement pin 12 described below.

The center of the protrusion 34 and the center of the through hole 35 are preferably located at the same position. That is, the center of the protrusion 34 and the center of the through hole 35 overlap with each other in a planar view. The positional relationship between the protrusion 34 and the through hole 35 is not limited thereto, and can appropriately be changed. The protrusion 34 and the through hole 35 are only required to at least partially overlap in a planar view.

For example, the through hole 35 may be included in the protrusion 34.

Although details will be described below, the outside surface of the protrusion 34 functions as positioning (first positioning portion) of the case 3 with respect to the metal base plate 11, and the inside surface of the protrusion 34 (through hole 35) functions as positioning (second positioning portion) of the semiconductor module 1 with respect to the attaching target base 10. As for the protrusion 34 and the through hole 11b, the centers of the circumscribed circle of the protrusion 34 and the inscribed circle of the through hole 11b preferably coincide with each other in a planar view.

The main terminal and the semiconductor unit 2 are electrically connected by the wiring member W1. For example, the interconnect plate 52 constituting a part of the interconnect path of the upper arm and the plate-like portion 80c of the P terminal 80 are electrically connected by the wiring member W1. The main electrode 60 of the semiconductor element 6 constituting the upper arm and the plate-like portion 82c of the M terminal 82 are electrically connected by the wiring member W1.

The main electrode 60 of the semiconductor element 6 constituting the lower arm and the plate-like portion 81c of the N terminal 81 are electrically connected by the wiring member W1. The interconnect plate 52 constituting a part of the interconnect path of the lower arm and the plate-like portion 82c of the M terminal 82 are electrically connected by the wiring member W1.

These wiring members W1 constitute a part of the main current path and may be referred to as main current wiring members. As the wiring member W1, a conductive wire (bonding wire) may be used. For example, as illustrated in FIG. 4, stitch bonding may be performed on the main electrode 60.

Also, the control electrode 61 of the semiconductor element 6 and the plate-like portion 83b of the control terminal 83 are electrically connected by the wiring member W2. The wiring member W2 may be referred to as a control wiring member. As the wiring member W2, a conductive wire (bonding wire) may be used.

As the material for the conductive wire constituting each of the wiring members W1 and W2, one of gold, copper, aluminum, a gold alloy, a copper alloy, and an aluminum alloy or any combination thereof can be used. As each of the wiring members W1 and W2, a member other than the conductive wire can be used. For example, a ribbon can be used as each of the wiring members W1 and W2. In addition, as the wiring member W1, a metal interconnect plate (which may be referred to as a lead frame) may be used.

Next, a configuration of the attaching target base 10 will be described. The attaching target base 10 has a rectangular shape in a planar view larger than the outer shape of the semiconductor module 1 (metal base plate 11). The attaching target base 10 is made of a metal having good heat dissipation properties. The attaching target base 10 may be made of, for example, aluminum, an aluminum alloy, copper, or a copper alloy.

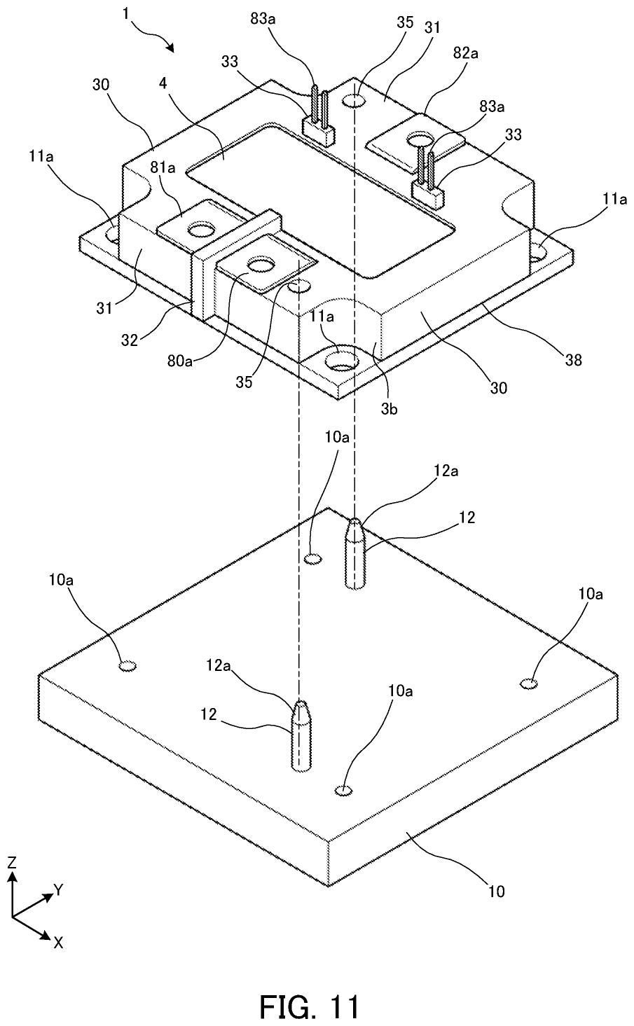

The upper surface of the attaching target base 10 constitutes an attachment surface to which the lower surface of the semiconductor module 1 (metal base plate 11) is attached. Screw holes 10a (refer to FIGS. 3 and 11) are formed at four corners of the attaching target base 10. The screw holes 10a are formed at corresponding positions immediately below the through holes 11a of the metal base plate 11. The screw holes 10a function as securing holes for the bolts B when the semiconductor module 1 is attached to the attaching target base 10.

The attaching target base 10 is provided with the engagement pin 12 in the vicinity of a predetermined screw hole 10a. The engagement pin 12 has a cylindrical shape protruding toward the positive side in the Z direction. A tapered surface 12a that is tapered is formed at the tip of the engagement pin 12. Two engagement pins 12 are disposed to be opposed to each other diagonally with the semiconductor unit 2 interposed therebetween in a planar view. Although details will be described below, the engagement pin 12 functions as an engagement portion (second engagement portion) for positioning the semiconductor module 1. The centers of the engagement pin 12 and the through hole 35 preferably coincide with each other.

The attaching target base 10 may constitute a box-shaped cooling jacket surrounding a plurality of fins (not illustrated) arranged on the lower surface of the metal base plate 11. That is, the attaching target base 10 may constitute a part of the cooler.

When the semiconductor module 1 is assembled, the metal base plate 11 and the case 3 are aligned and then connected. In this case, mutual positioning is necessary. Also, when the semiconductor module 1 is attached to the attaching target base 10, alignment (positioning) between the semiconductor module 1 and the attaching target base 10 is required.

Conventionally, the positioning configuration between the case 3 and the metal base plate 11 at the time of assembling the semiconductor module 1 and the positioning configuration between the metal base plate 11 and the attaching target base 10 at the time of mounting the semiconductor module 1 to the attaching target base 10 are separately provided. For this reason, there is a problem that component shapes become complicated due to the configurations for achieving positioning, resulting in an increase in cost.

Therefore, the present inventors have arrived at the present invention by focusing on the positional relationship between the positioning configuration at the time of module assembly and the positioning configuration at the time of module attachment. That is, the gist of the present invention is to achieve two types of positioning by a single positioning configuration into which the two positioning configurations are integrated. This can simplify the configuration, reduce the cost, and facilitate the assembly work and the attachment work.

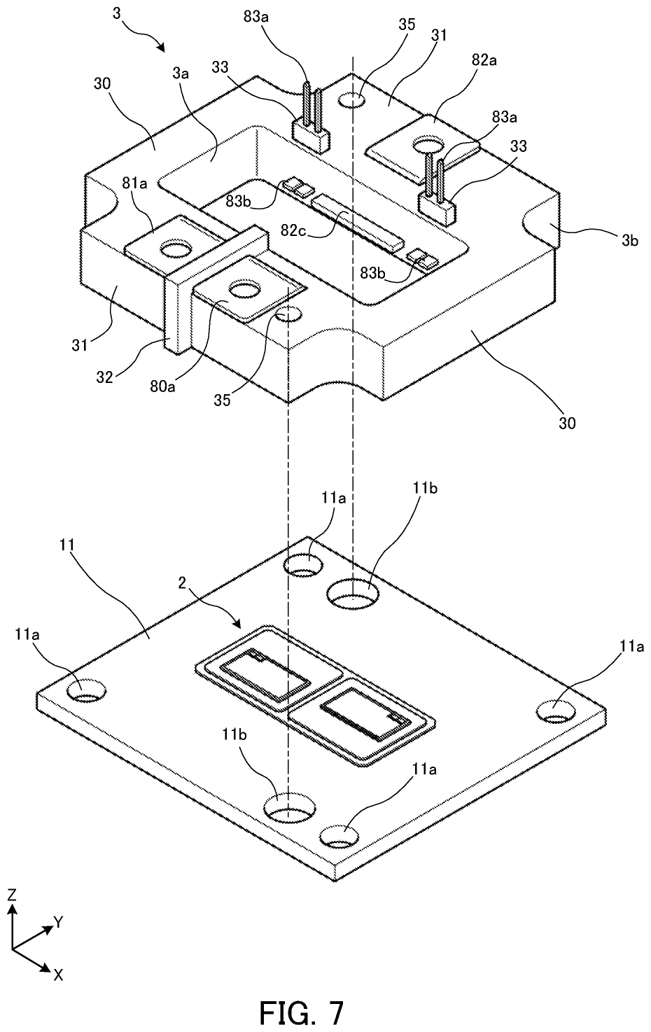

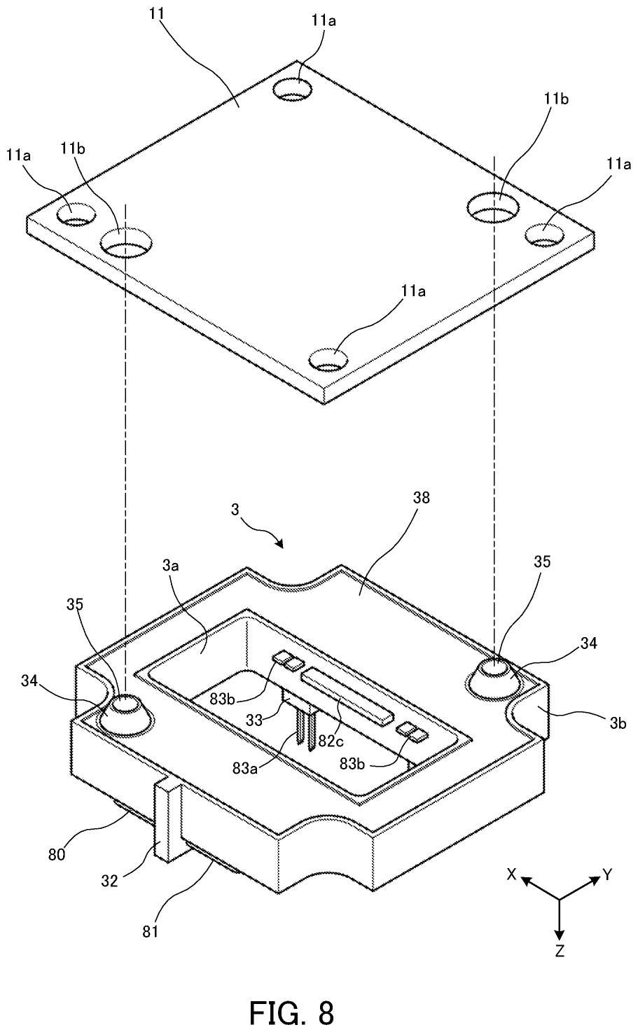

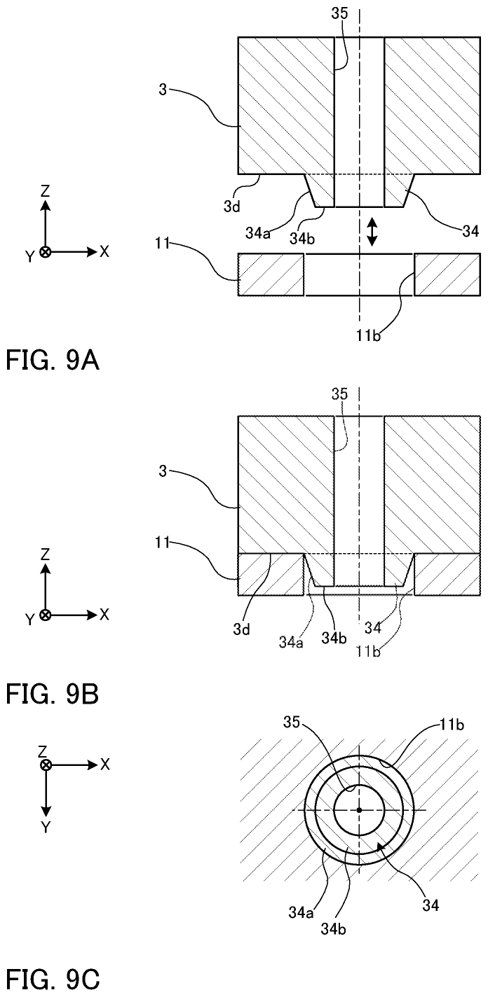

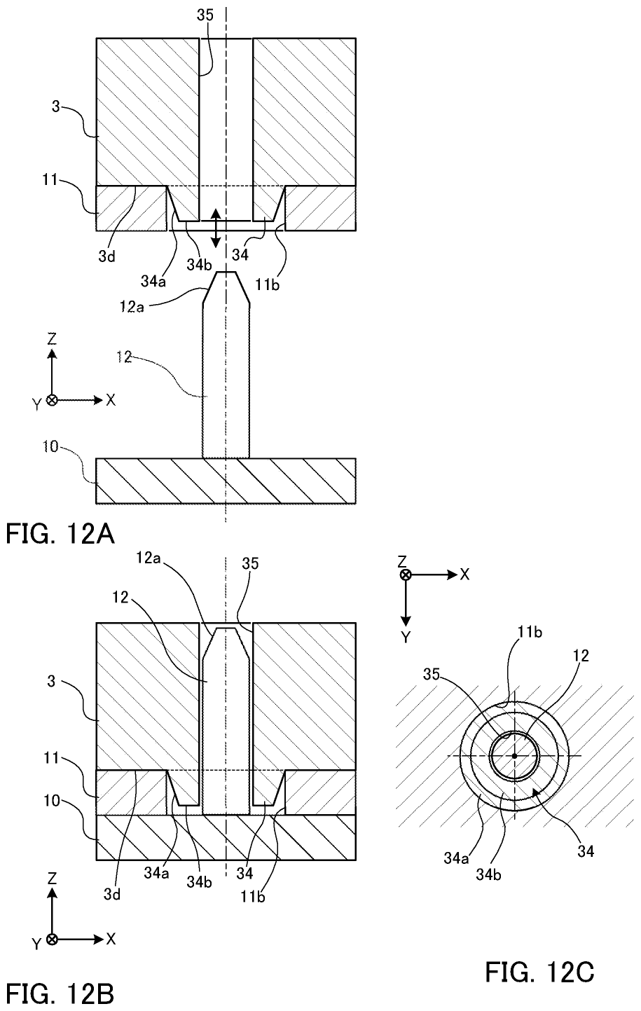

Hereinbelow, a detailed structure of the semiconductor device and a method for manufacturing the semiconductor device according to the present embodiment will be described with reference to FIGS. 6 to 12. FIGS. 6, 7, 8, 10, and 11 are perspective views each illustrating a process example of the method for manufacturing the semiconductor device according to the present embodiment. FIG. 8 is a perspective view of the process illustrated in FIG. 7 as viewed from the negative side in the Z direction. FIG. 9 illustrates schematic cross-sectional views enlarging a part of the process illustrated in FIG. 8. FIGS. 9A and 9B illustrate states before and after case mounting, and FIG. 9C is a partial cross-sectional view of FIG. 9B as viewed from the negative side in the Z direction. FIG. 12 illustrates schematic cross-sectional views enlarging a part of the process illustrated in FIG. 11. FIGS. 12A and 12B illustrate states before and after module attachment, and FIG. 12C is a partial cross-sectional view of FIG. 12B as viewed from the negative side in the Z direction. Each of the processes described below is merely an example, and the order of the processes can be changed as appropriate within a range not causing contradiction.

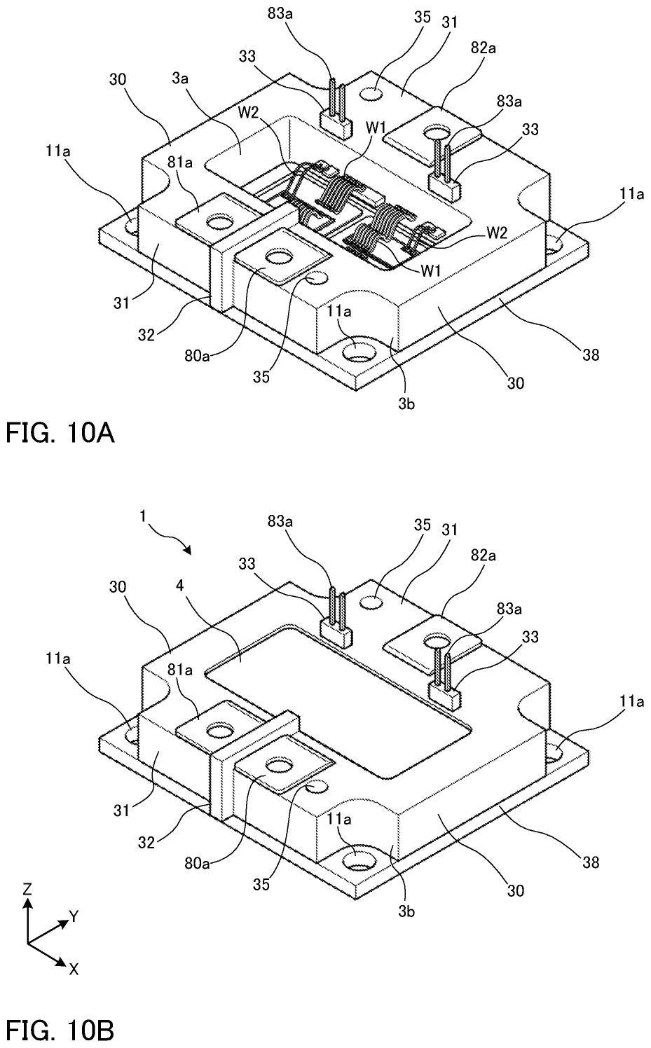

The method for manufacturing the semiconductor device according to the present embodiment includes a semiconductor unit mounting process (refer to FIG. 6), a case mounting process (refer to FIGS. 7 to 9A to 9C), a bonding process (refer to FIG. 10A), a sealing process (refer to FIG. 10B), and a module attaching process (refer to FIGS. 11 and 12A to 12C).

First, the semiconductor element 6 is mounted on the upper surface of the stacked substrate 5 in advance to form the semiconductor unit 2. The semiconductor element 6 is bonded to the upper surface of the stacked substrate 5 via a bonding material (not illustrated) such as solder. Thus, the semiconductor unit 2 is formed.

Then, the semiconductor unit mounting process is performed. As illustrated in FIG. 6, in the semiconductor unit mounting process, the semiconductor unit 2 is mounted on the upper surface of the metal base plate 11. Specifically, the heat dissipation plate 51 located on the lower surface side of the stacked substrate 5 is bonded to the upper surface of the metal base plate 11 via a bonding material such as solder.

Subsequently, the case mounting process is performed. As illustrated in FIGS. 7 to 9, in the case mounting process, the upper surface of the metal base plate 11 and the lower surface of the case 3 are connected to each other via an adhesive (not illustrated). At this time, the protrusion 34 engages with the through hole 11b opposed thereto, so that the center of the protrusion 34 and the center of the through hole 11b coincide with each other (FIG. 9C), and the case 3 is positioned with respect to the metal base plate 11. In this case, the inner diameter of the through hole 11b is preferably equal to or larger than the outer diameter of the base end portion of the protrusion 34.

The protrusion 34 has the tapered surface 34a that is tapered, and thus even in a case where the center positions of the protrusion 34 and the through hole 11b are misaligned with each other when the protrusion 34 is inserted into the through hole 11b, the protrusion 34 is inserted until the base end reaches the edge of the through hole 11b while the tapered surface 34a is in contact with the edge of the through hole 11b. Therefore, the protrusion 34 and the through hole 11b relatively move on the XY plane so that the mutual centers may coincide with each other while the tapered surface 34a serves as a guide surface, and a self-alignment function is exerted. As a result, the positioning of the case 3 with respect to the metal base plate 11 can be achieved with high accuracy.

In the case mounting process, the protrusion 34 functions as a “first positioning portion” of the case 3 with respect to the metal base plate 11. On the other hand, the through hole 11b functions as a “first engagement portion” with which the protrusion 34 (first positioning portion) is engageable.

Subsequently, the bonding process is performed. As illustrated in FIG. 10A, in the bonding process, the wiring members W1 and W2 are bonded at predetermined positions. As a result, the predetermined main terminal and the semiconductor unit 2 are electrically connected, and the predetermined control terminal 83 and the predetermined control electrode 61 are electrically connected.

Subsequently, the sealing process is performed. As illustrated in FIG. 10B, in the sealing process, the internal space of the case 3 is filled with the sealing resin 4. The sealing resin 4 is supplied at a depth to cover various components (semiconductor unit 2, wiring members W1 and W2, main terminal, and part of control terminal 83) in the space. By curing the sealing resin 4, the various components are sealed. Thus, the semiconductor module 1 is completed.

Subsequently, the module attaching process is performed. As illustrated in FIGS. 11 and 12, in the module attaching process, the semiconductor module 1 is attached to the attaching target base 10. Specifically, first, the semiconductor module 1 is positioned above the attaching target base 10 such that the through hole 11a of the metal base plate 11 overlaps with the screw hole 10a of the attaching target base 10 in a planar view.

At this time, the through hole 35 of the case 3 and the engagement pin 12 of the attaching target base 10 are also positioned so as to overlap with each other in a planar view. Then, as the through hole 35 engages with the engagement pin 12, the center of the through hole 35 and the center of the engagement pin 12 coincide with each other, and the semiconductor module 1 (case 3) is positioned with respect to the attaching target base 10. In this case, the inner diameter of the through hole 35 is preferably equal to or larger than the outer diameter of the engagement pin 12.

The engagement pin 12 has the tapered surface 12a that is tapered, and thus even in a case where the center positions of the engagement pin 12 and the through hole 35 are misaligned with each other when the engagement pin 12 is inserted into the through hole 35, the engagement pin 12 is inserted until the base end reaches the edge of the through hole 35 while the tapered surface 12a is in contact with the edge of the through hole 35. Therefore, the engagement pin 12 and the through hole 35 relatively move on the XY plane so that the mutual centers may coincide with each other while the tapered surface 12a serves as a guide surface, and a self-alignment function is exerted.

At this time, the centers of the through holes 11a coincide with the centers of the corresponding screw holes 10a, and the positioning of the semiconductor module 1 (case 3) with respect to the attaching target base 10 can be achieved with high accuracy. Then, the attaching target base 10 and the semiconductor module 1 can be fastened and secured using the bolts B. In this manner, the semiconductor device 100 in which the semiconductor module 1 and the attaching target base 10 are integrated is obtained.

In the module attaching process, the through hole 35 of the case 3 functions as the “second positioning portion” of the semiconductor module 1 with respect to the attaching target base 10. On the other hand, the engagement pin 12 functions as the “second engagement portion” with which the through hole 35 (second positioning portion) is engageable. In the present embodiment, since the second positioning portion is the through hole 35, the engagement pin 12 can be visually recognized from the upper surface of the case 3 through the through hole 35 at the time of attachment. Accordingly, attachment workability can be improved.

In this manner, in the present embodiment, the protrusion 34 (first positioning portion) and the through hole 35 (second positioning portion) are disposed so as to overlap with each other in a planar view. According to this configuration, it is possible to perform positioning (first positioning) of the case 3 at the time of module assembly and positioning (second positioning) at the time of attaching the completed semiconductor module 1 to the attaching target base 10 only with use of the cylindrical protrusion 34.

That is, it is possible to perform two positioning functions with use of a single configuration. The configuration can be simplified, the cost can be reduced, and the assembly work and the attachment work can be facilitated. In addition, the space required for the configuration for positioning can be minimized, and the entire device can be downsized. Note that the protrusion 34 may be referred to as a single positioning portion formed by pairing the first positioning portion and the second positioning portion with each other.

In the present embodiment, two single positioning portions (protrusions 34) are disposed to be opposed to each other diagonally with the semiconductor unit 2 interposed therebetween. The two positioning portions can prevent relative rotation between the components to be positioned.

The protrusion height of the protrusion 34 is preferably lower than the thickness of the metal base plate 11. With this configuration, when the semiconductor module 1 is attached to the attaching target base 10, the protrusion 34 can be prevented from contacting the attachment surface.

In the above embodiment, the first positioning portion is the circular protrusion 34 including at least an arc portion in a planar view. The second positioning portion is the circular through hole 35 including at least an arc portion in a planar view. The protrusion 34 and the through hole 35 have the centers thereof overlap with each other in a planar view. As a result, the single positioning portion can be achieved by the cylindrical protrusion 34.

However, the present invention is not limited thereto, and the protrusion 34 can appropriately be changed. The centers of the protrusion 34 and the through hole 35 may be misaligned with each other in a planar view. The protrusion 34 and the through hole 35 are only required to overlap in a planar view. Similarly, the centers of the through hole 11b and the engagement pin 12 corresponding thereto may be misaligned with each other.

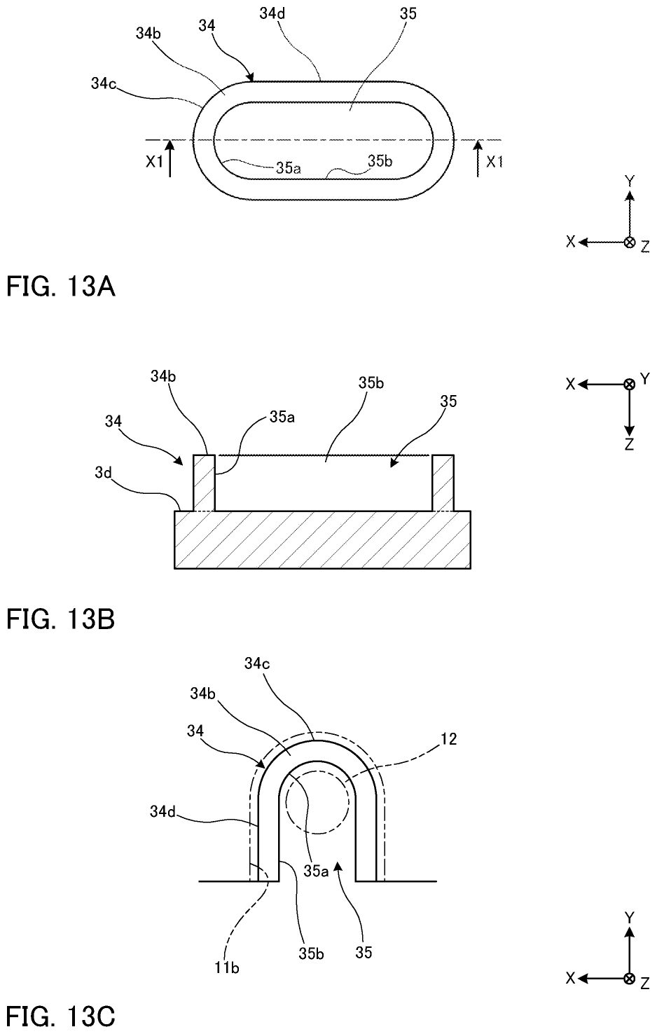

In the above embodiment, the case where the protrusion 34 and the through hole 35 have a circular shape in a planar view has been described, but the present invention is not limited to this configuration. For example, a configuration as in a modification example illustrated in FIGS. 13A and 13B may be available. FIG. 13A is a schematic plan view of the protrusion 34 and the through hole 35 according to the modification example, and FIG. 13B is a cross section taken along line X1-X1 in FIG. 13A. In FIGS. 13A and 13B, the protrusion 34 and the through hole 35 each have an elliptic shape elongated in the X direction in a planar view.

Specifically, the protrusion 34 includes, in addition to the flat surface 34b described above, a pair of arc portions 34c and a pair of linear portions 34d connecting the paired arc portions 34c. The paired arc portions 34c each have a semicircular shape and are opposed to each other in the X direction. The paired linear portions 34d are opposed to each other in the Y direction. The through hole 35 includes a pair of arc portions 35a and a pair of linear portions 35b connecting the paired arc portions 35a. The paired arc portions 35a each have a semicircular shape and are opposed to each other in the X direction. The paired linear portions 35b are opposed to each other in the Y direction. The protrusion 34 and the through hole 35 have the centers thereof overlap with each other in a planar view and have similar shapes. In this case, the through hole 11b (first engagement portion) to be engaged with the protrusion 34 also preferably includes a linear portion. According to the configuration, the relative rotation between the members can be suppressed only by the single protrusion 34 (positioning portion), and the configuration can further be simplified.

In the above embodiment, the case where the second positioning portion is a hole has been described, but the present invention is not limited to this configuration. For example, as illustrated in FIG. 13C, the second positioning portion may be a cutout 35. In FIG. 13C, the protrusion 34 has a U shape in a planar view in which the arc portion 34c having a semicircular shape and the linear portions 34d extending in the Y direction from both the ends of the arc portion 34c are connected. Similarly, the cutout 35 has a U shape in a planar view in which the arc portion 35a having a semicircular shape and the linear portions 35b provided at both the ends of the arc portion 35a are connected. The protrusion 34 and the cutout 35 have the centers of the arc portion 34c and the arc portion 35a overlap with each other and have similar shapes. According to the configuration, the single positioning portion can be arranged close to the outer periphery of the case 3, and the entire device can further be downsized.

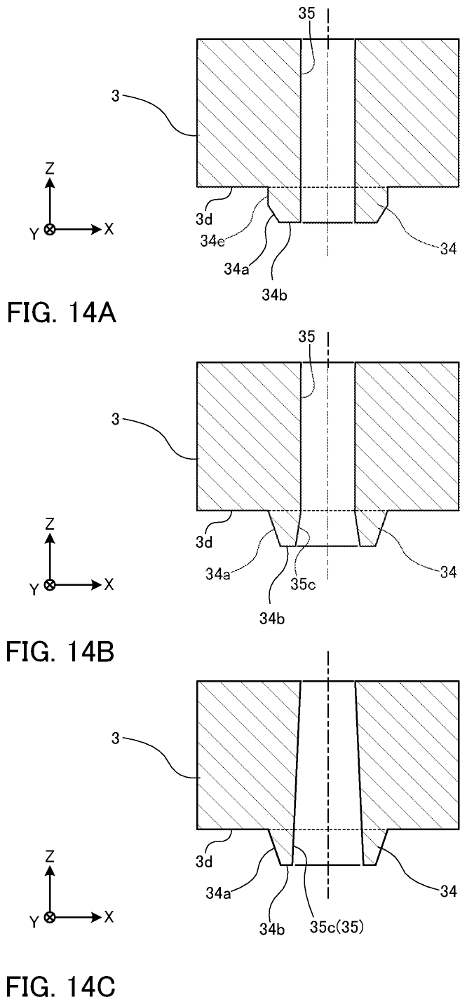

Although the protrusion 34 described in the above embodiment has a shape in which the flat surface 3d and the flat surface 34b are directly connected by the tapered surface 34a, the present invention is not limited thereto, and can appropriately be changed. For example, as illustrated in FIG. 14A, the protrusion 34 may include a vertical surface 34e between the flat surface 3d and the tapered surface 34a, for example. The vertical surface 34e is a cylindrical surface erected in the Z direction so as to be perpendicular to the flat surface 3d (34b). The vertical surface 34e connects the flat surface 3d with the tapered surface 34a.

As illustrated in FIGS. 14B and 14C, a tapered surface 35c may be formed on the inside surface of the through hole 35 so as to reduce in diameter from the lower end side (the side provided with the protrusion 34) toward the upper side in the Z direction. That is, the tapered surface 35c is inclined so as to increase in diameter toward the lower end. As illustrated in FIG. 14B, the tapered surface 35c may be formed at the entrance of the through hole 35 (the end on the side provided with the protrusion 34). As illustrated in FIG. 14C, the tapered surface 35c may be formed on the entire inside surface of the through hole 35. The tapered surface 35c facilitates insertion of the engagement pin 12.

In the above-described embodiment, the number and arrangement location of the semiconductor element 6 are not limited to the above-described configuration, and can appropriately be changed.

Furthermore, in the above-described embodiment, the number and layout of the interconnect plate are not limited to the above-described configuration, and can be changed as appropriate.

In the above-described embodiment, the stacked substrate 5 and the semiconductor element 6 each have a rectangular shape or a square shape in a planar view, but the present invention is not limited to this configuration. These components may each have a polygonal shape other than the above.

The present embodiment and the modification examples have been described, but as another embodiment, the above-described embodiment and modification examples may be wholly or partially combined.

Furthermore, the present embodiment is not limited to the above-described embodiment and modification examples, and various changes, substitutions, and modifications may be made without departing from the spirit of the technical idea. When the technical idea can be achieved in another manner by the progress of the technology or another derived technology, the technical idea may be carried out by using the manner. Therefore, the claims cover all embodiments that may be included within the scope of the technical idea.

Feature points in the embodiment described above will be summarized below.

A semiconductor module according to the above-described embodiment includes a metal base plate on an upper surface of which a semiconductor unit including a semiconductor element is mounted, and a case which is bonded to the upper surface of the metal base plate and surrounds a periphery of the semiconductor unit. The case includes a first positioning portion formed by a protrusion protruding toward the metal base plate, and a second positioning portion formed by a hole or a cutout so as to at least partially overlap with the first positioning portion in a planar view. The metal base plate includes a first engagement portion formed by a hole or a cutout with which the first positioning portion is engageable.

Also, in the semiconductor module according to the above-described embodiment, the second positioning portion is included in the first positioning portion in a planar view. Also, in the semiconductor module according to the above-described embodiment, at least two single positioning portions each formed by pairing the first positioning portion and the second positioning portion with each other are arranged.

Also, in the semiconductor module according to the above-described embodiment, the two single positioning portions are disposed to be opposed to each other diagonally with the semiconductor unit interposed therebetween.

Also, in the semiconductor module according to the above-described embodiment, the first positioning portion is formed by a protrusion including an arc portion in a planar view, the second positioning portion includes an arc portion in a planar view, and centers of the arc portions of the first positioning portion and the second positioning portion overlap with each other in a planar view.

Also, in the semiconductor module according to the above-described embodiment, the second positioning portion has a circular shape in a planar view.

Also, in the semiconductor module according to the above-described embodiment, the first positioning portion has a circular shape in a planar view, and a center of the first positioning portion and a center of the second positioning portion overlap with each other in planar view.

Also, in the semiconductor module according to the above-described embodiment, the second positioning portion is formed by a cutout including a linear portion in a planar view.

Also, in the semiconductor module according to the above-described embodiment, the first positioning portion includes a linear portion in a planar view.

Also, in the semiconductor module according to the above-described embodiment, a protrusion height of the protrusion is lower than a thickness of the metal base plate.

Also, in the semiconductor module according to the above-described embodiment, the protrusion has a tapered surface that tapers toward a tip end.

In addition, a semiconductor device according to the above-described embodiment includes the semiconductor module, and an attaching target base which has an attachment surface to which a lower surface of the semiconductor module is attached. The attaching target base includes on the attachment surface a second engagement portion with which the second positioning portion is engageable.

Also, in the semiconductor device according to the above-described embodiment, the second engagement portion includes a pin that is disposed at a corresponding position immediately below the second positioning portion and extends toward the semiconductor module.

Also, in the semiconductor device according to the above-described embodiment, the pin has a circular shape in a planar view, and a center of the second positioning portion and a center of the pin overlap with each other.

Also, in the semiconductor device according to the above-described embodiment, the pin is provided with a tapered surface that tapers toward a tip end.

In addition, a method for manufacturing a semiconductor device according to the above-described embodiment includes a case mounting process of connecting the metal base plate to the case by engaging the first positioning portion with the first engagement portion, and a module attaching process of attaching the semiconductor module to the attaching target base by engaging the second positioning portion with the second engagement portion.

### INDUSTRIAL APPLICABILITY

As described above, the present invention has the effect of simplifying a configuration, reducing cost, and facilitating assembly work and attachment work, and is particularly useful for a semiconductor module for electric equipment or industrial use, a semiconductor device, and a method for manufacturing a semiconductor device.

The present application is based on Japanese Patent Application No. 2022-025012 filed on Feb. 21, 2022. All the contents are included here.

### REFERENCE SIGNS LIST

1 Semiconductor module
2 Semiconductor unit
3 Case
3a Opening
3b Cutout
3c Circular hole
4 Sealing resin
5 Stacked substrate
6 Semiconductor element
10 Attaching target base
10a Screw hole
11 Metal base plate
11a Through hole
11b Through hole (first engagement portion)
12 Engagement pin (second engagement portion)
12a Tapered surface
30 Sidewall
31 Sidewall
32 Partition wall
33 Column portion
34 Protrusion (first positioning portion)
34a Tapered surface
34b Flat surface
34c Arc portion
34d Linear portion
35 Through hole, cutout (second positioning portion)
35a Arc portion
35b Linear portion
35c Tapered surface
50 Insulating plate
51 Heat dissipation plate
52 Interconnect plate
60 Main electrode
61 Control electrode
80 P terminal
80a Plate-like portion
80b Circular hole
80c Plate-like portion
81 N terminal
81a Plate-like portion
81b Circular hole
81c Plate-like portion
82 M terminal
82a Plate-like portion
82b Circular hole
82c Plate-like portion
83 Control terminal
83a Pin portion
83b Plate-like portion
100 Semiconductor device
B Bolt
W1 Wiring member
W2 Wiring member

What is claimed is:

1. A semiconductor module, comprising:
a metal base plate having a semiconductor unit including a semiconductor element, the metal base plate having an upper surface and a bottom surface opposite to each other and the semiconductor element being mounted on the upper surface; and
a case surrounding a periphery of the semiconductor unit, a bottom of the case being bonded to the upper surface of the metal base plate, wherein
the case includes
a first positioning portion formed by a protrusion protruding from the bottom of the case toward the metal base plate, and
a second positioning portion formed by a hole or a cutout so as to at least partially overlap the first positioning portion in a plan view of the semiconductor module, and
the metal base plate includes a first engagement portion formed by a hole or a cutout with which the first positioning portion is engageable.

2. The semiconductor module according to claim 1, wherein the second positioning portion is provided within the first positioning portion in the plan view.

3. The semiconductor module according to claim 1, wherein the first positioning portion and the second positioning portion form a single positioning portion, and the single positioning portion is provided in plurality.

4. The semiconductor module according to claim 3, wherein the plurality of single positioning portions includes two single positioning portions that are disposed in diagonal opposition to each other with the semiconductor unit interposed therebetween.

5. The semiconductor module according to claim 1, wherein
the protrusion includes an arc portion in the plan view so that the first positioning portion has an arc portion,
the second positioning portion includes an arc portion in the plan view, and
centers of the arc portions of the first positioning portion and the second positioning portion overlap each other in the plan view.

6. The semiconductor module according to claim 5, wherein the second positioning portion has a circular shape in the plan view.

7. The semiconductor module according to claim 6, wherein
the first positioning portion has a circular shape in the plan view, and
a center of the first positioning portion and a center of the second positioning portion overlap each other in the plan view.

8. The semiconductor module according to claim 1, wherein the second positioning portion is formed by the cutout, the cutout having a linear portion in the plan view.

9. The semiconductor module according to claim 1, wherein the first positioning portion includes a linear portion in the plan view.

10. The semiconductor module according to claim 1, wherein a height of the protrusion is lower than a thickness of the metal base plate in a thickness direction.

11. The semiconductor module according to claim 1, wherein an outer surface of the protrusion is tapered toward a tip end.

12. A semiconductor device, comprising:
the semiconductor module according to claim 1; and
an attaching target base having an attachment surface to which a lower surface of the semiconductor module is attached, wherein
the attaching target base includes on the attachment surface a second engagement portion with which the second positioning portion is engageable.

13. The semiconductor device according to claim 12, wherein the second engagement portion includes a pin that is disposed at a position corresponding to immediately below a position of the second positioning portion and extends toward the semiconductor module.

14. The semiconductor device according to claim 13, wherein the pin has a circular shape in the plan view, and a center of the second positioning portion and a center of the pin overlap each other.

15. The semiconductor device according to claim 13, wherein an outer surface of the pin is tapered toward a tip end of the pin.

16. A method for manufacturing the semiconductor device according to claim 12, the method comprising:
connecting the metal base plate to the case by engaging the first positioning portion with the first engagement portion; and
attaching the semiconductor module to the attaching target base by engaging the second positioning portion with the second engagement portion.
